(19) United States
(12) Patent Application Publication
(10) Pub. No.: US 2014/0125397 A1
(43) Pub. Date: May 8, 2014

(54) LEVEL CONVERTER FOR CONTROLLING SWITCH

(71) Applicant: Soongsil University Research Consortium Techno-Park, Seoul (KR)

(72) Inventors: Chang Kun Park, Suwon-si (KR); Chang Hyun Lee, Seoul (KR); Suk Hyeon Yun, Seoul (KR)

(73) Assignee: Soongsil University Research Consortium Techno-Park, Seoul (KR)

(21) Appl. No.: 13/962,014

(22) Filed: Aug. 8, 2013

(30) Foreign Application Priority Data
Nov. 8, 2012 (KR) 10-2012-0126359

(51) Int. Cl. H03K 19/0185

(52) U.S. Cl. CPC H03K 19/018521
USPC 327/333

(57) ABSTRACT

Provided is a power amplifier using a differential structure. The power amplifier includes: first and second transistors whose first terminals are each connected to a first power supply source supplying a first voltage and into which signals having the same size and opposite polarities are input; third and fourth transistors whose first terminals are respectively connected to the first terminals of the first and second transistors; and a fifth transistor whose first terminal is connected to second terminals of the third and fourth transistors and controlling oscillation of the third or fourth transistor.

### CROSS-REFERENCE TO RELATED PATENT APPLICATION

This application claims the benefit of Korean Patent Application No. 10-2012-0126359, filed on Nov. 8, 2012, in the Korean Intellectual Property Office, the disclosure of which is incorporated herein in its entirety by reference.

### BACKGROUND OF THE INVENTION

1. Field of the Invention

The present invention relates to a level converter for controlling a switch, and more particularly, to a level converter for controlling a switch such that a main switch included in a direct current (DC)-DC converter or a rectifier normally operates.

2. Description of the Related Art

Currently, a direct current (DC) voltage converting circuit (DC-DC converter) that converts a voltage of a battery to a constant voltage is widely used in a wireless power transmission system. Specifically, the DC-DC converter that is small, has excellent converting efficiency, and uses a switching method is used in a portable electronic device. The DC-DC converter is an adjustor using a pulse width modulation (PWM) method, includes a main switching transistor and a synchronization transistor, and alternately turns on and off the main switching transistor and the synchronization transistor. A main switch is turned on to supply energy from an inlet to an outlet, and is turned off to emit energy accumulated in an inductor. Also, by controlling a pulse width of a pulse signal driving the main switch according to an output voltage or output current, the output voltage is almost uniformly maintained.

FIG. 1 is a block diagram of a receiver of a general wireless power transmission system. As shown in FIG. 1, alternating current (AC) power input from an antenna is converted into a DC voltage through a rectifier, and the DC voltage is controlled to a DC voltage desired by a user through a DC-DC converter. Here, in order to output the desired DC voltage from the DC-DC converter, a duty of an output signal of a switch controller using a PWM method is adjusted.

FIG. 2A is a block diagram of a DC-DC converter and a switch controller for controlling an output power value of the DC-DC converter, and FIG. 2B illustrates an example of an actual circuit diagram to which the DC-DC converter of FIG. 2A is applied. The DC-DC converter of FIG. 2B has a buck shape. A region indicated to be a switch in FIG. 2B may be an NMOS or a PMOS. A control signal V_{CTRL} is applied to a gate of the NMOS or PMOS, and the NMOS or PMOS used as the switch may be turned on or off according to the control signal V_{CTRL}.

Generally, in FIG. 2B, a size of an output voltage of the DC-DC converter is increased when a turn-on time is longer than a turn-off time of the switch, and is decreased when the turn-off time is longer than the turn-on time. As such, the size of the output voltage of the DC-DC converter may be controlled based on a ratio of the turn-on time and the turn-off time according to the control signal V_{CTRL}.

FIG. 3A is a circuit diagram of a DC-DC converter including a PMOS type switch, according to a conventional technology, and FIGS. 3B and 3C illustrate voltage changes according to switching operations.

Generally, when V_{S} denotes a source voltage of the PMOS type switch, V_{G} denotes a gate voltage, V_{D} denotes a drain voltage, and V_{TH} denotes a threshold voltage, the PMOS type switch is turned on when a condition of V_{G}<V_{S}−V_{TH} is satisfied, and is turned off when a condition of V_{G}>V_{S}−V_{TH} is satisfied. When the PMOS type switch is applied to the circuit diagram of FIG. 3A, the PMOS type switch is turned off when a condition of V_{TH}>V_{IN}−V_{CTRL} is satisfied and is turned on when a condition of V_{TH}<V_{IN}−V_{CTRL} is satisfied as shown in FIG. 3B

However, when an input voltage V_{IN} of the DC-DC converter is abnormally increased as shown in FIG. 3C, the condition of V_{TH}V_{IN}−V_{CTRL} is satisfied regardless of a value of a control signal V_{CTRL}, and thus the PMOS type switch is always turned on.

FIG. 4A is a circuit diagram of a DC-DC converter including an NMOS type switch, according to a conventional technology, and FIGS. 4B and 4C illustrate voltage changes according to switching operations.

When V_{S} denotes a source voltage of the NMOS type switch, V_{G} denotes a gate voltage, V_{D} denotes a drain voltage, and V_{TH} denotes a threshold voltage, the NMOS type switch is turned on when a condition of V_{G}>V_{S}+V_{TH} is satisfied, and is turned off when a condition of V_{G}<V_{S}+V_{TH} is satisfied. When the NMOS type switch is applied to the circuit diagram of FIG. 4A, the NMOS type switch is turned off when a condition of V_{TH}>V_{CTRL}−V_{A} is satisfied and is turned on when a condition of V_{TH}<V_{CTRL}−V_{A} is satisfied as shown in FIG. 4B.

However, when a voltage V_{A} of the DC-DC converter is abnormally decreased as shown in FIG. 4C, the condition of V_{TH}<V_{CTRL}−V_{A} is satisfied regardless of a value of a control signal V_{CTRL}, and thus the NMOS type switch is always turned on. Such problems of the DC-DC converters in FIGS. 3C and 4C may also be generated in a rectifier.

FIG. 5A is a circuit diagram of a rectifier including an NMOS type switch, according to a conventional technology, and FIGS. 5B and 5C illustrate voltage changes according to switching operations. Since control signals V_{CTRL}_{_{—}}_{A} and V_{CTRL}_{_{—}}_{B} input to both ends of the rectifier of FIG. 5A have different phases but have the same size, the control signals V_{CTRL}_{_{—}}_{A} and V_{CTRL}_{_{—}}_{B} are described to be a control signal V_{CTRL} for convenience of description.

Accordingly, as shown in FIG. 5B, the NMOS type switch of the rectifier is turned off when a condition of V_{TH}>V_{DTRL}−V_{OUT} is satisfied and is turned on when a condition of V_{TH}<V_{CTRL}−V_{OUT} is satisfied as described above with reference to FIG. 4B.

However, when a voltage V_{OUT} of the rectifier is abnormally decreased as shown in FIG. 5C, the condition of V_{TH}<V_{CTRL}−V_{OUT} is satisfied regardless of a value of the control signal V_{CTRL}, and thus the NMOS type switch is always turned on.

As such, as described above with reference to FIGS. 3C, 4C, and 5C, a switch is always turned on if an input voltage V_{IN} of a DC-DC converter is increased or an output voltage V_{OUT} is abnormally decreased, and thus on and off of the switch are unable to be controlled by a control signal V_{CTRL}. As a result, operations of the DC-DC converter are unable to be controlled.

### SUMMARY OF THE INVENTION

The present invention provides a level converter for controlling a switch such that a main switch included in a direct current (DC)-DC converter or a rectifier normally operates.

According to an aspect of the present invention, there is provided a level converter including: a first transistor whose source is connected to a first power supply source supplying a first voltage; a second transistor whose source is connected to the first power supply source and whose gate is connected to a drain of the first transistor; a third transistor whose drain is connected to the drain of the first transistor, whose gate receives a control signal, and whose source is connected to a second power supply source supplying a second voltage; and a fourth transistor whose drain is connected to a drain of the second transistor and a gate of the first transistor, whose gate is connected to the drain of the first transistor and the drain of the third transistor, and whose source is connected to the second power supply source, wherein a switch signal corresponding to a voltage applied to the drain of the second transistor is output to a main switch.

According to another aspect of the present invention, there is provided a level converter including: a first transistor whose source is connected to a first power supply source supplying a first voltage; a second transistor whose source is connected to the first power supply source and whose gate is connected to a drain of the first transistor; a third transistor whose drain is connected to the drain of the first transistor, whose gate receives a control signal, and whose source is connected to a second power supply source supplying a first voltage lower than the first voltage; a phase reverser whose input terminal is connected to the gate of the third transistor; and a fourth transistor whose drain is connected to a drain of the second transistor and a gate of the first transistor, whose gate is connected to an output terminal of the phase reverser, and whose source is connected to the second power supply source, wherein a switch signal having a voltage applied to the drain of the second transistor is output to a main switch.

The first and second transistors may have the same polarities, and may have different polarities from the third and fourth transistors.

The first and second transistors may be PMOS transistors and the third and fourth transistors may be NMOS transistors.

When a high level control signal is applied to the gate of the third transistor, the second and third transistors may be turned on and first and fourth transistors may be turned off.

When a low level control signal is applied to the gate of the third transistor, the second and third transistors may be turned off and the first and fourth transistors may be turned on.

The main switch may be a PMOS type, have a source connected to the first power supply source, and perform switching operations that are controlled as the switch signal is input through a gate.

When a high level control signal having a third voltage is applied to the gate of the third transistor, a high level switch signal having a fourth voltage higher than the third voltage may be input to a second terminal of the main switch.

The fourth voltage may have a same level as the first voltage and the second power supply source may be a ground source.

The main switch may be an NMOS type, have a drain connected to the first power supply source, and perform switching operations that are controlled as the switching signal is input through a gate.

When a low level control signal having a third voltage is applied to a second terminal of the third transistor, a low level switch signal having a fourth voltage lower than the third voltage may be input to a second terminal of the main switch.

The fourth voltage may have a same level as the second voltage.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a receiver of a general wireless power transmission system;

FIG. 2A is a block diagram of a direct current (DC)-DC converter and a switch controller for controlling an output power value of the DC-DC converter;

FIG. 2B illustrates an example of an actual circuit diagram to which the DC-DC converter of FIG. 2A is applied;

FIG. 3A is a circuit diagram of a DC-DC converter including a PMOS type switch, according to a conventional technology;

FIGS. 3B and 3C illustrate voltage changes according to switching operations;

FIG. 4A is a circuit diagram of a DC-DC converter including an NMOS type switch, according to a conventional technology;

FIGS. 4B and 4C illustrate voltage changes according to switching operations;

FIG. 5A is a circuit diagram of a rectifier including an NMOS type switch, according to a conventional technology;

FIGS. 5B and 5C illustrate voltage changes according to switching operations;

FIG. 6A is a diagram of a PMOS switch control circuit including a level converter, according to an embodiment of the present invention;

FIG. 6B illustrates a voltage change according to switching operations of the PMOS switch control circuit of FIG. 6A;

FIG. 7A is a circuit diagram of the level converter of FIG. 6A according to an embodiment of the present invention;

FIG. 7B is a circuit diagram of the level converter of FIG. 6A according to another embodiment of the present invention;

FIG. 8A is a diagram of an NMOS switch control circuit including a level converter, according to an embodiment of the present invention;

FIG. 8B illustrates a voltage change according to switching operations of the NMOS switch control circuit of FIG. 8A;

FIG. 9A is a circuit diagram of the level converter of FIG. 8A according to an embodiment of the present invention;

FIG. 9B is a circuit diagram of a level converter of FIG. 8A according to another embodiment of the present invention;

FIG. 10A is a circuit diagram of a rectifier including level converters, according to an embodiment of the present invention; and

FIG. 10B illustrates a voltage change according to switching operations of the rectifier of FIG. 10A.

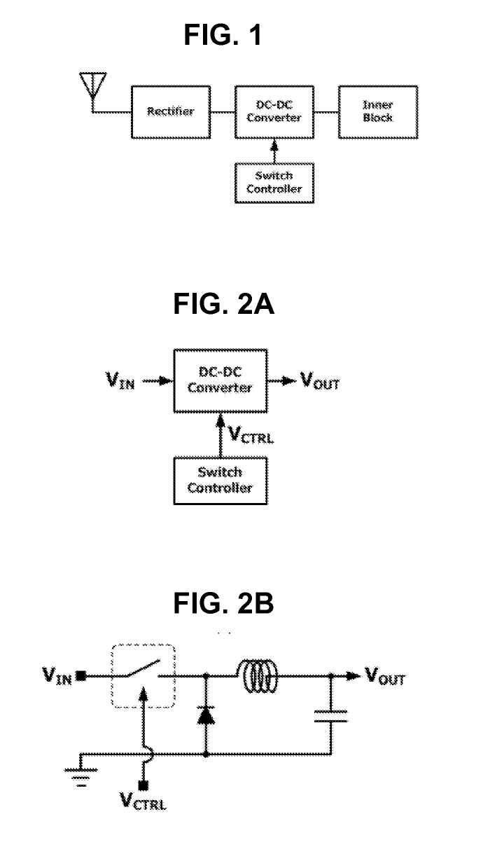

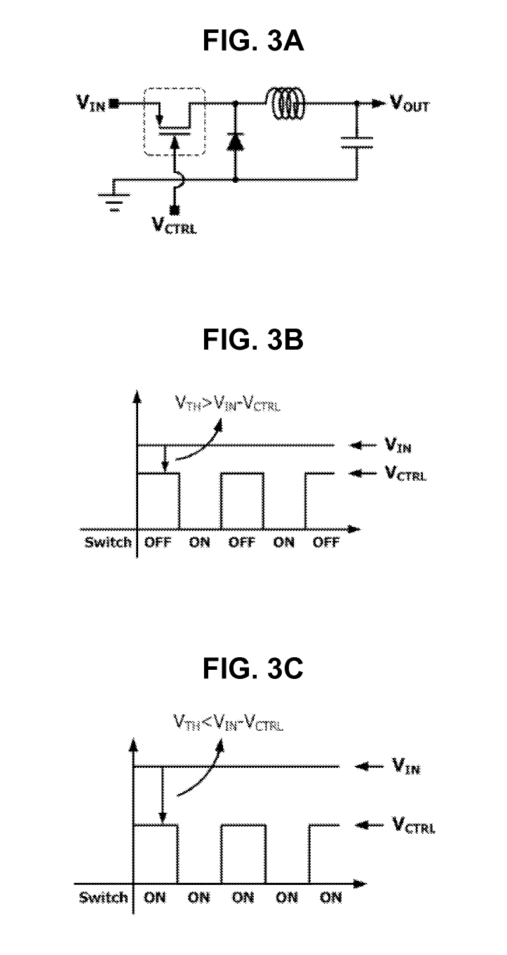

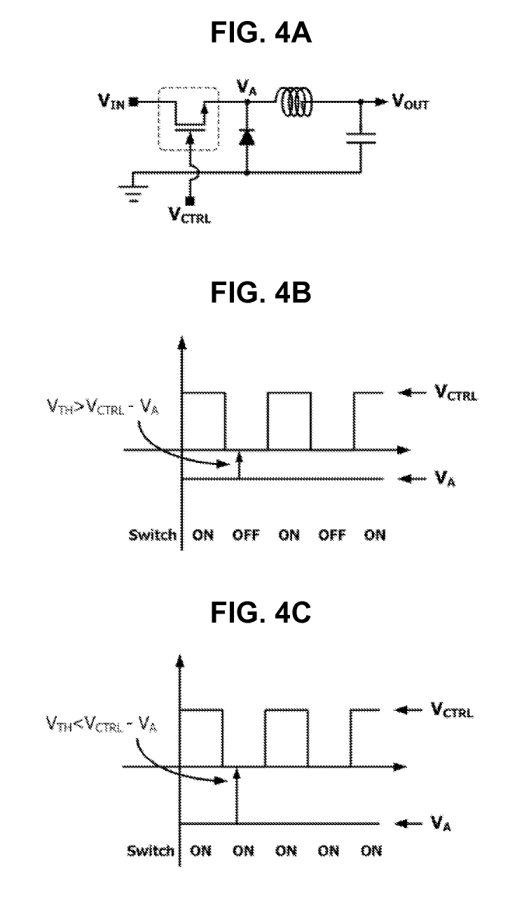

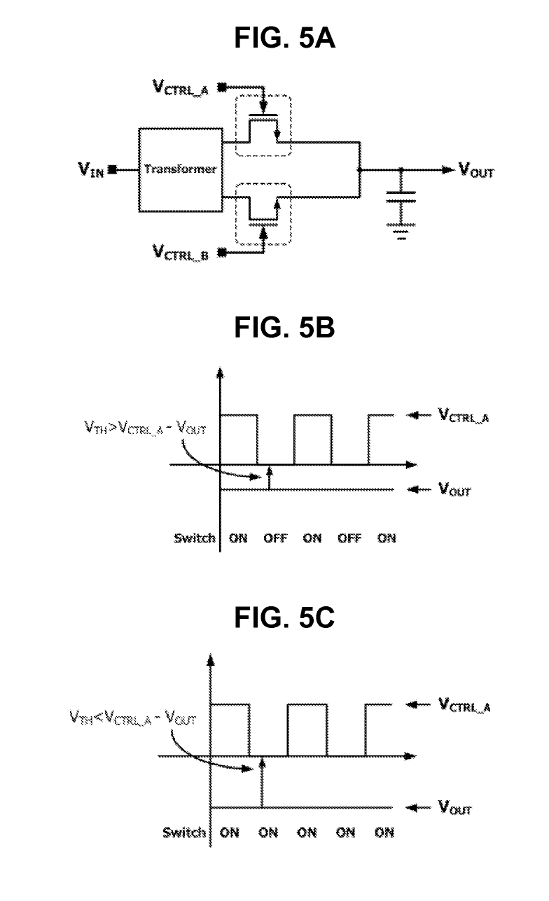

### DETAILED DESCRIPTION OF THE INVENTION

Hereinafter, embodiments the present invention will be described more fully with reference to the accompanying drawings to be easily executed by one of ordinary skill in the art. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In drawings, elements irrelevant to description are not shown for clear description, and like elements denote like reference numerals throughout the specification.

In the specification, when a region is “connected” to another region, the regions may not only be “directly connected”, but may also be “electrically connected” via another device therebetween. Also, when a region “includes” an element, the region may further include another element instead of excluding the other element, otherwise differently stated.

Also, throughout the specification, the expression that a voltage is maintained includes cases where a change of a potential difference between certain two points is within a range allowable according to designs even when the potential difference changes according to time, and where a reason for the change is a parasitic component ignored in customary designs by one of ordinary skill in the art. Also, since a threshold voltage of a semiconductor device (transistor, diode, or the like) is very low compared to a discharge voltage, the threshold voltage is considered to be 0 V and approximated.

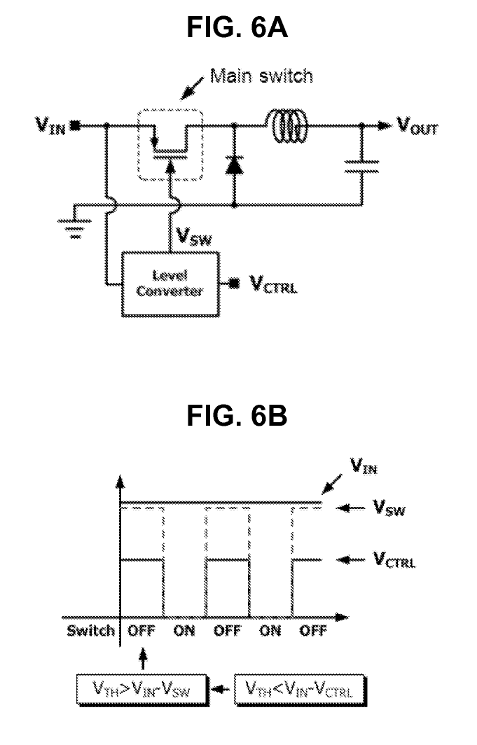

FIG. 6A is a diagram of a PMOS switch control circuit including a level converter, according to an embodiment of the present invention, and FIG. 6B illustrates a voltage change according to switching operations of the PMOS switch control circuit of FIG. 6A.

Referring to FIG. 6A, a main switch used in a direct current (DC)-DC converter is a PMOS type. As shown in FIG. 6A, the main switch has a source connected to a power supply source of an input voltage V_{IN}, has a gate connected to the level converter according to an embodiment of the present invention, and receives a switch signal V_{SW} from the level converter. Also, a drain of the main switch is connected to an output terminal.

Also, the level converter is connected to the power supply source of the input voltage V_{IN}, and outputs the switch signal V_{SW} to the gate of the main switch upon receiving a control signal V_{CTRL}. Accordingly, the switching operations of the main switch are controlled by the switch signal V_{SW} of the level converter.

FIG. 6B shows waveforms of the input voltage V_{IN}, the switch signal V_{SW}, and the control signal V_{CTRL} of FIG. 6A.

A swing of the waveform of the control signal V_{CTRL} input as shown in FIG. 6B is adjusted by a value of the input voltage V_{IN}, and thus the switch signal V_{SW} is output while the main switch is turned off. Accordingly, even when the input voltage V_{IN} is abnormally increased, a condition of V_{TH}>V_{IN}−V_{CTRL} is satisfied while the main switch is turned off, and thus such a PMOS type main switch may be maintained to be turned off. Accordingly, the main switch is not turned on even when a voltage of the control signal V_{CTRL} has a high value while the main switch is turned off.

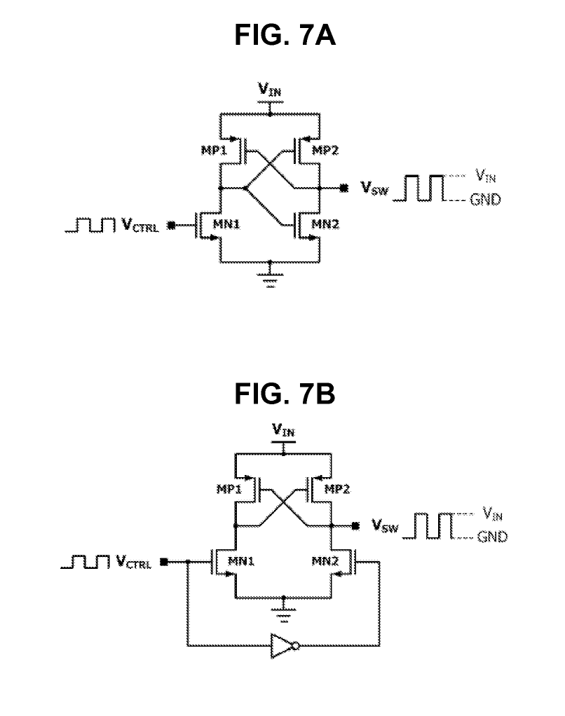

FIG. 7A is a circuit diagram of the level converter of FIG. 6A according to an embodiment of the present invention, and FIG. 7B is a circuit diagram of the level converter of FIG. 6A according to another embodiment of the present invention.

The level converters of FIGS. 7A and 7B may be used to transmit the control signal V_{CTRL} to the main switch of FIGS. 6A and 6B.

First, the level converter of FIG. 7A includes first and second transistors MP1 and MP2 that are PMOS types, and third and fourth transistors MN1 and MN2 that are

NMOS types. The first transistor MP1 has a source connected to the power supply source of the input voltage V_{IN} and a gate connected to drains of the second and fourth transistors MP2 and MN2.

The second transistor MP2 has a source connected to the power supply source of the input voltage V_{IN} and a gate connected to a drain of the first transistor MP1.

The third transistor MN1 has a drain connected to the drain of the first transistor MP1, receives the control signal V_{CTRL} through a gate, and has a source connected to a ground source. The control signal V_{CTRL} is used to control the switching operations of the main switch of the DC-DC converter, wherein the main switch is turned off when the control signal V_{CTRL} is a high level signal and is turned on when the control signal V_{CTRL} is a low level signal.

The fourth transistor MN2 has the drain connected to the drain of the second transistor MP2 and the gate of the first transistor MP1, has a gate connected to a contact point of the first and third transistors MP1 and MN1, and has a source connected to the ground source.

Also, the switch signal V_{SW} having a voltage corresponding to the drains of the second and fourth transistors MP2 and MN2 is applied to the gate of the main switch.

As shown in FIG. 7A, the level converter receives the control signal V_{CTRL} and the input voltage V_{IN}, and outputs the switch signal V_{SW}. Here, the input voltage V_{IN} is supplied as a power supply voltage of the level converter.

A process of a voltage value of the switch signal V_{SW} changing according to the control signal V_{CTRL} will now be described. For convenience of description, the input voltage V_{IN} is 5 V, and a high level voltage of the control signal V_{CTRL} is 3 V.

First, when the control signal V_{CTRL} is in a high level, the third transistor MN1 is turned on, and thus a drain voltage of the third transistor MN1 becomes 0 V, i.e., a ground voltage. Accordingly, since 0 V is applied to each of the gates of the second and fourth transistors MP2 and MN2, the second transistor MP2 is turned on and the fourth transistor MN2 is turned off.

As a result, 5 V corresponding to the input voltage V_{IN} is applied to the drains of the second and fourth transistors MP2 and MN2, and the switch signal V_{SW} having a value of the input voltage V_{IN} is output to the gate of the main switch as shown in FIG. 7A as the first transistor MP1 is turned off, and thus the main switch is turned off. As such, the voltage of the switch signal V_{SW} has the value of the input voltage V_{IN}. In other words, when the control signal V_{CTRL} in the high level and having a value of 3 V is input, the control signal V_{CTRL} is converted to the switch signal V_{SW} having the voltage (5 V) of the input voltage V_{IN} through the level converter, and thus a turn-off operation of the main switch may be normally performed even when the input voltage V_{IN} is abnormally increased.

Alternatively, when the control signal V_{CTRL} is in a low level, the third transistor MN1 is turned off, and thus the drain voltage of the third transistor MN1 becomes 5 V, i.e., the input voltage V_{IN}. Accordingly, since 5 V is applied to each of the gates of the second and fourth transistors MP2 and MN2, the second transistor MP2 is turned off and the fourth transistor MN2 is turned on.

As a result, 0 V corresponding to the ground voltage is applied to the drains of the second and fourth transistors MP2 and MN2, and the switch signal V_{SW} of 0 V is output to the gate of the main switch as shown in FIG. 7A as the first transistor MP1 is turned on, and thus the main switch is turned on. As such, the voltage of the switch signal V_{SW} has a value of 0 V. In other words, when the control signal V_{CTRL} in the low level and having a value of 0 V is input, the control signal V_{CTRL} is converted to the switch signal V_{SW} while maintaining 0 V even through the level converter, and thus a turn-on operation of the main switch may be normally performed.

Meanwhile, the level converter of FIG. 7B includes the first and second transistors MP1 and MP2 that are PMOS types and the third and fourth transistors MN1 and MN2 that are NMOS types. The first transistor MP1 has the source connected to the power supply source of the input voltage V_{IN} and has the gate connected to the drains of the second and fourth transistors MP2 and MN2.

The second transistor MP2 has the source connected to the power supply source of the input voltage V_{IN} and the gate connected to the drain of the first transistor MP1. The third transistor MN1 has the drain connected to the drain of the first transistor MP1, receives the control signal V_{CTRL} through the gate, and has the source connected to the ground source.

The fourth transistor MN2 has the drain connected to the drain of the second transistor MP2 and the gate of the first transistor MP1, and the source connected to the ground source.

Also, a phase reverser has an input terminal connected to the gate of the third transistor MN1 and an output terminal connected to the gate of the fourth transistor MN2.

Also, the switch signal V_{SW} having the voltage corresponding to the drains of the second and fourth transistors MP2 and MN2 is applied to the gate of the main switch.

First, when the control signal V_{CTRL} is in a high level, the third transistor MN1 is turned on and 0 V, i.e., a low level voltage, is applied to the gate of the fourth transistor MN2 by the phase reverser, and thus the fourth transistor MN2 is turned off.

Accordingly, the drain voltage of the third transistor MN1 becomes the ground voltage of 0 V, and thus the second transistor MP2 is turned on, 5 V corresponding to the input voltage V_{IN} is applied to the drain of the second transistor MP2, and the first transistor MP1 is turned off.

As such, 5 V corresponding to the input voltage V_{IN} is applied to the drains of the second and fourth transistors MP2 and MN2, and the switch signal V_{SW} having the value of the input voltage V_{IN} is output to the gate of the main switch as shown in FIG. 7A as the first transistor MP1 is turned off, and thus the main switch is turned off. Accordingly, the voltage of the switch signal V_{SW} has the value of the input voltage V_{IN}. Thus, when the control signal V_{CTRL} in the high level and having a value of 3 V is input, the control signal V_{CTRL} is converted to the switch signal V_{SW} having the voltage of 5 V of the input voltage V_{IN} through the level converter, and thus the turn-off operation of the main switch may be normally performed even when the input voltage V_{IN} is abnormally increased.

Also, when the control signal V_{CTRL} is in the low level, the third transistor MN1 is turned off, and the fourth transistor MN2 is turned on as 3 V, i.e., the high level voltage is applied to the gate of the fourth transistor MN2 by the phase reverser.

Accordingly, since the drain voltage of the fourth transistor MN2 is 0 V, i.e., the ground voltage, the first transistor MP1 is turned on and 5 V, i.e., the input voltage V_{IN} is applied to the gate of the second transistor MP2, and thus the second transistor MP2 is turned off.

As a result, 0 V corresponding to the ground voltage is applied to the drains of the second and fourth transistors MP2 and MN2, and the switch signal V_{SW} having the value of 0 V is output to the gate of the main switch as shown in FIG. 7A as the first transistor MP1 is turned on, and thus the main switch is turned on. As such, the voltage of the switch signal V_{SW} has a value of 0 V. In other words, when the control signal V_{CTRL} in the low level and having the value of 0 V is input, the control signal V_{CTRL} is converted to the switch signal V_{SW} while maintaining 0 V even through the level converter, and thus the turn-on operation of the main switch may be normally performed.

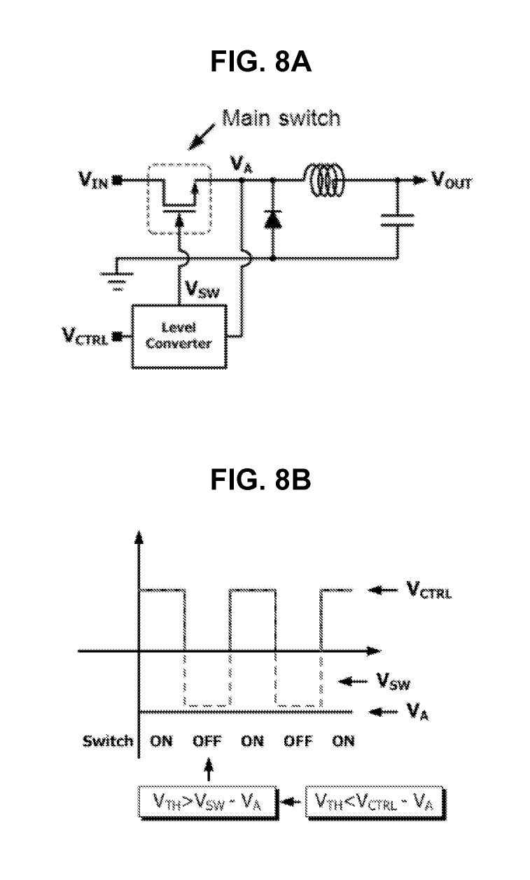

FIG. 8A is a diagram of an NMOS switch control circuit including a level converter, according to an embodiment of the present invention, and FIG. 8B illustrates a voltage change according to switching operations of the NMOS switch control circuit of FIG. 8A.

In FIG. 8A, the main switch used in the DC-DC converter is an NMOS type. As shown in FIG. 8A, the main switch as the drain connected to the power supply source of the input voltage V_{IN}, the gate connected to the level converter according to an embodiment of the present invention, and receives the switch signal V_{SW} from the level converter. Also, the drain of the main switch is connected to the output terminal, wherein an input voltage V_{A} applied to the drain of the main switch is applied to the level converter.

Also, the level converter receives the input voltage V_{A} by being connected to the source of the main switch, and outputs the switch signal V_{SW} to the gate of the main switch upon receiving the control signal V_{CTRL}. Accordingly, the switching operations of the main switch are controlled by the switch signal V_{SW} of the level converter.

FIG. 8B shows waveforms of the input voltage V_{A}, the switch signal V_{SW}, and the control signal V_{CTRL} of FIG. 8A.

A swing of the waveform of the control signal V_{CTRL} input as shown in FIG. 8B is adjusted by the value of the input voltage V_{IN}, and thus the switch signal V_{SW} is output while the main switch is turned off. Accordingly, even when the input voltage V_{A} is abnormally decreased, a condition of V_{TH}>V_{IN}−V_{A} is satisfied while the main switch is turned off, and thus such an NMOS type main switch may be maintained to be turned off. Accordingly, the main switch is not turned on even when the voltage of the control signal V_{CTRL} has a low value while the main switch is turned off.

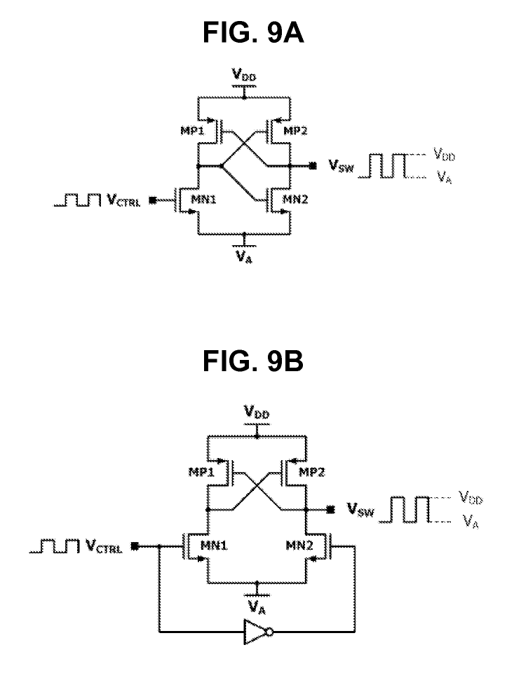

FIG. 9A is a circuit diagram of the level converter of FIG. 8A according to an embodiment of the present invention, and FIG. 9B is a circuit diagram of a level converter of FIG. 8A according to another embodiment of the present invention.

The level converters of FIGS. 9A and 9B may be used to transmit the control signal V_{CTRL} to the main switch of FIGS. 8A and 8B.

The level converters of FIGS. 9A and 9B are the same as the level converters of FIGS. 7A and 7B in terms of circuit configurations and operations, except that the input voltage V_{A} of FIGS. 8A and 8B is used in the level converters of FIGS. 9A and 9B instead of the ground voltage.

In other words, according to the level converters of FIGS. 9A and 9B, when the control signal V_{CTRL} in the high level and having the value of 3 V is input, the control signal V_{CTRL} is converted to the switch signal V_{SW} having the value (5 V) of the input voltage V_{IN} through the level converter, and thus the turn-off operation of the main switch may be normally performed even when the input voltage V_{IN} is abnormally increased.

Also, when the control single V_{CTRL} in the low level and having the value of 0 V is input, the control signal V_{CTRL} is converted to the switch signal V_{SW} having the value of the input voltage V_{A} through the level converter, and thus the turn-on operation of the main switch may be normally performed.

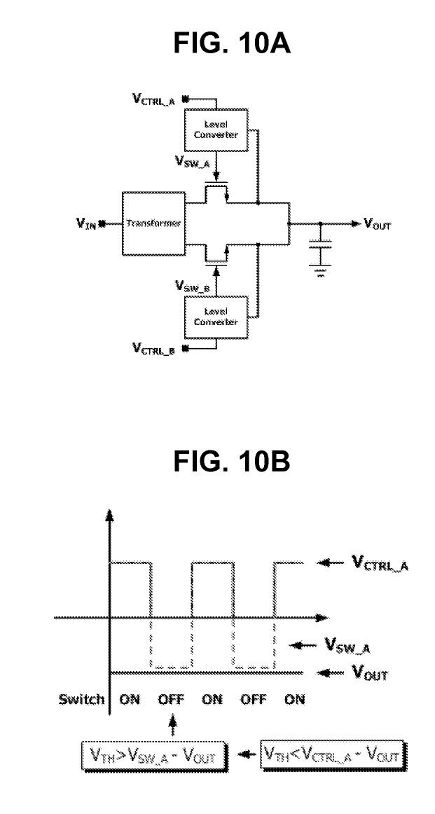

FIG. 10A is a circuit diagram of a rectifier including level converters, according to an embodiment of the present invention, and FIG. 10B illustrates a voltage change according to switching operations of the rectifier of FIG. 10A.

Referring to FIG. 10A, two main switches used in the rectifier are both NMOS types. In FIG. 10A, V_{CTRL}_{_{—}}_{A} and V_{SW}_{_{—}}_{A} respectively indicate a control signal and a switch signal applied to the level converter at the top and V_{CTRL}_{_{—}}_{A} and V_{SW}_{_{—}}_{B} respectively denote a control signal and a switch signal applied to the level converter at the bottom. The level converter of FIG. 10A receives an output voltage V_{OUT} and the control signal V_{CTRL} of the main switch, and outputs the switch signal V_{SW}. Here, since the control signals V_{CTRL}_{_{—}}_{A} and V_{CTRL}_{_{—}}_{B}, and the switch signals V_{SW}_{_{—}}_{A} and V_{SW}_{_{—}}_{B} have the same sizes and different phases, only the level converter at the top will be described for convenience.

The main switch at the top in FIG. 10A has the drain connected to a transformer, the gate connected to level converter, and the source connected to the output terminal. Here, the transformer receives the input voltage V_{IN} and transmits the input voltage V_{IN} to the main switch. The level converter outputs the switch signal V_{SW}_{_{—}}_{A} to the gate of the main switch upon receiving the control signal V_{CTRL}_{_{—}}_{A}. Accordingly, the switching operations of the main switch are controlled by the switch signal V_{SW}_{_{—}}_{A} of the level converter.

FIG. 10B shows waveforms of the input voltage V_{A}, the switch signal V_{SW}, and the control signal V_{CTRL} of FIG. 10A.

A swing of the waveform of the control signal V_{CTRL} input as shown in FIG. 10B is adjusted according to a value of the output voltage V_{OUT}, and thus the switch signal V_{SW} is output while the main switch is turned off. Accordingly, even when the output voltage V_{OUT} is abnormally decreased, a condition of V_{TH}>V_{SW}_{_{—}}_{A}−V_{OUT} is satisfied while the main switch is turned off, and thus such an NMOS type main switch may be maintained to be turned off. Accordingly, the main switch is not turned on even when the control signal V_{CTRL} has a low level value while the main switch is turned off.

As described above, according to one or more embodiments of the present invention, by providing a level converter at a gate terminal of a main switch in order to control the main switch constituting a DC-DC converter, the main switch may be normally operated. In other words, according to one or more embodiments of the present invention, an NMOS and a PMOS constituting the main switch of the DC-DC converter may be prevented from being always turned on or off without being normally operated as an input voltage is changed in the DC-DC converter or a voltage of an internal node of the DC-DC converter is abnormally changed.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A level converter comprising:
a first transistor whose source is connected to a first power supply source supplying a first voltage;
a second transistor whose source is connected to the first power supply source and whose gate is connected to a drain of the first transistor;
a third transistor whose drain is connected to the drain of the first transistor, whose gate receives a control signal, and whose source is connected to a second power supply source supplying a second voltage; and
a fourth transistor whose drain is connected to a drain of the second transistor and a gate of the first transistor, whose gate is connected to the drain of the first transistor and the drain of the third transistor, and whose source is connected to the second power supply source,
wherein a switch signal corresponding to a voltage applied to the drain of the second transistor is output to a main switch.

2. A level converter comprising:
a first transistor whose source is connected to a first power supply source supplying a first voltage;
a second transistor whose source is connected to the first power supply source and whose gate is connected to a drain of the first transistor;
a third transistor whose drain is connected to the drain of the first transistor, whose gate receives a control signal, and whose source is connected to a second power supply source supplying a first voltage lower than the first voltage;
a phase reverser whose input terminal is connected to the gate of the third transistor; and
a fourth transistor whose drain is connected to a drain of the second transistor and a gate of the first transistor, whose gate is connected to an output terminal of the phase reverser, and whose source is connected to the second power supply source,
wherein a switch signal having a voltage applied to the drain of the second transistor is output to a main switch.

3. The level converter of claim 1, wherein the first and second transistors have the same polarities, and have different polarities from the third and fourth transistors.

4. The level converter of claim 3, wherein the first and second transistors are PMOS transistors and the third and fourth transistors are NMOS transistors.

5. The level converter of claim 4, wherein, when a high level control signal is applied to the gate of the third transistor, the second and third transistors are turned on and first and fourth transistors are turned off.

6. The level converter of claim 5, wherein, when a low level control signal is applied to the gate of the third transistor, the second and third transistors are turned off and the first and fourth transistors are turned on.

7. The level converter of claim 6, wherein the main switch is a PMOS type, has a source connected to the first power supply source, and performs switching operations that are controlled as the switch signal is input through a gate.

8. The level converter of claim 7, wherein, when a high level control signal having a third voltage is applied to the gate of the third transistor, a high level switch signal having a fourth voltage higher than the third voltage is input to a second terminal of the main switch.

9. (canceled)

10. The level converter of claim 6, wherein the main switch is an NMOS type, has a drain connected to the first power supply source, and performs switching operations that are controlled as the switching signal is input through a gate.

11. The level converter of claim 10, wherein, when a low level control signal having a third voltage is applied to a second terminal of the third transistor, a low level switch signal having a fourth voltage lower than the third voltage is input to a second terminal of the main switch.

12. The level converter of claim 11, wherein the fourth voltage has a same level as the second voltage.

13. The level converter of claim 2, wherein the first and second transistors have the same polarities, and have different polarities from the third and fourth transistors.

14. The level converter of claim 13, wherein the first and second transistors are PMOS transistors and the third and fourth transistors are NMOS transistors.

15. The level converter of claim 14, wherein, when a high level control signal is applied to the gate of the third transistor, the second and third transistors are turned on and first and fourth transistors are turned off.

16. The level converter of claim 15, wherein, when a low level control signal is applied to the gate of the third transistor, the second and third transistors are turned off and the first and fourth transistors are turned on.

17. The level converter of claim 16, wherein the main switch is a PMOS type, has a source connected to the first power supply source, and performs switching operations that are controlled as the switch signal is input through a gate.

18. The level converter of claim 17, wherein, when a high level control signal having a third voltage is applied to the gate of the third transistor, a high level switch signal having a fourth voltage higher than the third voltage is input to a second terminal of the main switch.

19. The level converter of claim 16, wherein the main switch is an NMOS type, has a drain connected to the first power supply source, and performs switching operations that are controlled as the switching signal is input through a gate.

20. The level converter of claim 19, wherein, when a low level control signal having a third voltage is applied to a second terminal of the third transistor, a low level switch signal having a fourth voltage lower than the third voltage is input to a second terminal of the main switch.

21. The level converter of claim 20, wherein the fourth voltage has a same level as the second voltage.
